(19) United States
(12) Patent Application Publication
(10) Pub. No.: US 2024/0155770 A1
(43) Pub. Date: May 9, 2024

(54) PRINTED CIRCUIT BOARD, METAL-CERAMIC SUBSTRATE AS AN INSERT, AND PROCESS FOR MANUFACTURING SUCH AN INSERT

(71) Applicant: ROGERS GERMANY GMBH, Eschenbach (DE)

(72) Inventors: Andreas MEYER, Speichersdorf (DE); Olivier MATHIEU, Kempen (DE)

(21) Appl. No.: 18/280,995

(22) PCT Filed: Feb. 23, 2022
(86) PCT No.: PCT/EP2022/054529

§ 371 Date: Sep. 8, 2023

(30) Foreign Application Priority Data
Mar. 8, 2021 (DE) 10 2021 105 529.6

(51) Int. Cl. H05K 1/18; H05K 1/03; H05K 3/42; H05K 3/46

(52) U.S. Cl. CPC H05K 1/185; H05K 1/0306; H05K 3/422; H05K 3/4694

(57) ABSTRACT

Printed circuit board (100) for electrical components (5) and/or conducting paths (4), comprising
a base body (2) extending along a main extension plane (HSE), and
an insert (1) integrated in the base body (2),
   wherein the insert (1) comprises a metal-ceramic substrate (15), an electrical and/or electronic component (5), and an encapsulation (10) enclosing at least the electrical and/or electronic component (5).

### CROSS-REFERENCE TO RELATED APPLICATIONS

This application is a National Stage filing of PCT/EP2022/054529, filed Feb. 23, 2022, which claims priority to DE 10 2021 105 529.6, filed Mar. 8, 2021, both of which are incorporated by reference in their entirety herein.

### BACKGROUND

The present invention relates to a printed circuit board, a metal-ceramic substrate as an insert for such a printed circuit board, and a method of manufacturing such an insert.

Printed circuit boards are sufficiently known from the prior art. Such printed circuit boards serve as a carrier for electrical circuits which are formed or composed of conducting paths, electrical components and/or connections. The electrical circuits are preferably formed on one component side of the printed circuit board. Such printed circuit boards, also known as PCBs (printed circuit boards), are usually made of plastic, in particular fiber-reinforced plastic, epoxy resin and/or hard paper. The use of such materials has proven to be particularly cost-effective and easy to handle during the manufacturing process. However, it has been found that said printed circuit board materials have limited thermal conductivity, which is, however, necessary to dissipate heat emanating from electrical components during operation. In addition, the insulation capability is limited. As the performance of electronic components increases, printed circuit boards manufactured from the usual materials are therefore unsuitable for permanently withstanding the stresses generated during operation and providing good insulating properties.

On the other hand, printed circuit boards configured as metal-ceramic substrates are characterized by high insulation capability and they typically have higher thermal conductivities compared to those of the above-mentioned materials. However, the production of metal-ceramic substrates is more complex and cost-intensive than the production of printed circuit boards made of plastic, epoxy resin and/or hard paper.

Based on the prior art, the present invention aims to provide printed circuit boards that meet the demanding requirements for heat dissipation and insulation capability of electronic components, and at the same time can be produced at a lower cost.

### SUMMARY

This task is solved by the printed circuit board as described herein, the insert as described herein and the method as described herein. Further embodiments can be found in the subsequent claims and the description.

According to a first aspect of the present invention, a printed circuit board for electrical components and/or conducting paths, is intended comprising
a base body extending along a main extension plane, and
an insert integrated into the base body,
   wherein the insert comprises a metal-ceramic substrate, an electrical and/or electronic component, and an encapsulation enclosing at least the electrical and/or electronic component.

### BRIEF DESCRIPTION OF THE DRAWINGS

Further advantages and features result from the following description of more preferably embodiments of the object according to the invention with reference to the attached figures. Individual features of the individual embodiment can thereby be combined with one another within the scope of the invention, wherein in the figures:

FIG. 1: schematic representation of a printed circuit board according to a first more preferably embodiment of the present invention in a plan view (top) and a sectional view (bottom);

FIGS. 2a-2c: Examples of more preferably embodiments of the inserts according to the present invention;

FIGS. 3a, 3b: Further examples of embodiments of inserts according to the present invention;

FIGS. 4a-4c: Further examples of embodiments of inserts according to the present invention;

FIGS. 5a-5d: Further examples of embodiments for inserts according to the present invention;

FIGS. 6a-6d: Further examples of embodiments for inserts according to the present invention;

FIGS. 7a,7b: Examples of embodiments of printed circuit boards according to the present invention; and

FIG. 8: Further embodiment example for an insert according to one of the preceding claims.

### DETAILED DESCRIPTION

Compared with printed circuit boards known from the prior art, it is intended according to the invention that the base body of the printed circuit board is not formed entirely from one of the common materials, such as plastic, hard paper and/or epoxy resin, but that only a section of the printed circuit board is formed from the insert according to the claims at least. In particular, the metal-ceramic substrate equipped with the encapsulated component is embedded or inserted in the base body of the printed circuit board in order to specifically provide locally for increased thermal conductivity. This makes it possible, for example, to insert or embed inserts in the printed circuit board in areas where increased heat generation is to be expected. At the same time, it is possible to manufacture the majority of the base body from a material, such as a plastic, in particular a fiber-reinforced plastic, epoxy resin or a hard paper, which is cost-effective and easy to work with.

In particular, it proves advantageous to provide those electrical or electronic components which exhibit increased heat generation during operation immediately in an environment which is in each case adapted to the heat generation of the respective component. This is advantageously realized with the insert according to the claims, in which consideration is given to the respective heat development emanating from the electrical component by a corresponding design of the metal-ceramic substrate, for example with regard to the dimensioning of the component metallization and/or backside metallization and/or ceramic element along a stacking direction running perpendicular to the main extension plane. For example, it is conceivable that a thickness of the component metallization of the metal-ceramic substrate is adapted to the respective heat generation of the component in order to provide the fastest possible heat dissipation for the respective component. The respective inserts then only need to be inserted into the base bodies of the printed circuit board. An electrical bond is provided between the component and the outside of the insert for powering and driving the component. Preferably, only a single component is intended for an insert in each case, or the insert comprises a plurality of components. Furthermore, the skilled person understands by an enclosing encapsulation of the component that the component is not exposed at any side, i.e., any outer side.

In addition, it is possible that by means of the encapsulation the electrical and electronic components are also protected from the outside. In addition, the integration of the component into the base body is simplified and only the bond between insert-side connections, i.e., connections on the insert, and the corresponding conducting paths and/or connections on the printed circuit board must be realized. In addition, the components integrated in the encapsulation no longer protrude from the outside of the printed circuit board, which further protects them from the environment of the respective printed circuit board.

Preferably, it is intended that the insert, in particular with a correspondingly profiled sidewall, form-fitted in the installed state cooperates with the base body in a direction parallel to the stacking direction. In addition, it is conceivable that the form-fitted bond between the base body and the insert is supported by an adhesively bonded and/or force-fitted connection.

Furthermore, it is in particular intended that a proportion of the insert or inserts in the proportion of the printed circuit board is less than 30%, more preferably less than 20% and most preferably less than 10%. Furthermore, it is intended that the insert extends from the component side of the base body to the back side of the base body of the printed circuit board. In other words, the insert is substantially flush with the base body in a direction perpendicular to the main extension plane on both sides, i.e., the component side and the back side. The form-fitted connection between the base body and the metal-ceramic substrate serving as the insert provides, in particular, a permanent bond between the metal-ceramic substrate and the base body, which prevents the insert from becoming detached from the printed circuit board. Preferably, the form-fit acts in both possible directions, which are perpendicular to the main extension plane of the base body. Furthermore, it is conceivable that further inserts are arranged in the base body in addition to the insert. It is also conceivable that the insert is flush with the base body only on the component side and the back side of the metal-ceramic substrate is enclosed by the base body. In other words, the metal-ceramic substrate or insert is recessed or inserted in a recess in the base body of the printed circuit board. This also results in a form-fitted connection parallel to the main extension plane.

In particular, it is intended that the metal-ceramic substrate and the base body are configured such that their thermal expansion coefficients are as similar as possible. In other words, a difference in the thermal expansion coefficients of the insert and the base body is kept as small as possible. For this purpose, for example, a corresponding thickness of the ceramic element is set in the metal-ceramic substrate. It is also conceivable that a stabilization layer is intended for adapting the thermomechanical coefficient of expansion, or that several metal layers and/or different metallizations (e.g., component metallizations and back metallizations are manufactured from different metals or materials) are used to provide the desired adaptation in a corresponding manner. In this way, it can be ensured that no significant mechanical stresses arise between the base body and the metal-ceramic substrate as a result of extensions occurring during operation, which could lead to cracking, for example. Preferably, it is also conceivable that different ceramic elements are used in a metal-ceramic substrate.

It has proved advantageous if, in addition to the form-fit, a material bond is realized between the lateral surface of the insert and the base body.

According to a more preferable embodiment, it is intended that for forming the form-fitted cooperation
the insert, preferably the metal-ceramic substrate and/or the encapsulation, is profiled on a lateral surface not parallel to the main extension plane and/or
a ceramic element of the metal-ceramic substrate and or a part of the insert protrudes in a direction parallel to the main extension plane opposite a component metallization and/or the backside metallization of the metal-ceramic substrate.

For example, it is intended that a lateral surface, in particular a lateral surface of the encapsulation, the component metallization and/or backside metallization is concavely and/or convexly curved or bowed. Alternatively, it is also conceivable that the insert is formed in a stepped manner on its sidewall or lateral surface. In particular, it is intended that the base body engage the recessed and/or protruding progressions on the lateral surfaces of the encapsulation, metallization and/or back metallization so as to cause the form-fit in a direction or both directions that are perpendicular to the main extension plane. For example, it is conceivable that the outermost edge of the encapsulation or component metallization is stepped, in particular stepped in such a way that the open region of the step is formed on the side facing the component side and/or the back side. In a corresponding manner, a component can be arranged on the component metallization in such a way that, considering an isotropic transport of the heat, the heat spread is completely covered by the component metallization. The sections of the component metallization which do not contribute to the heat transfer here anyway are removed in this stepped course in an appropriate manner and replaced by the base body. Preferably, a protruding section of the ceramic element is used to form the form-fitted joint. In particular, this is the section known as the pullback, which provides sufficient isolation between the component metallization and the backside metallization.

Preferably, it is intended that the insert has a maximum extension in a plane dimensioned parallel to the main extension plane, which has a value between 1 mm and 200 mm, more preferably between 4 mm and 60 mm and most preferably between 6 mm and 30 mm. This provides comparatively small-dimensioned inserts which can be used as required for a local increase in thermal conductivity in the printed circuit board. In particular, comparatively many individual inserts can be provided from a master card. Such a master card is defined by the format immediately after the connection of the component metallization to the backside metallization, which is carried out via an appropriate connection process.

In particular, the lateral surface is intended to be profiled in such a way that it has a modulation depth or height that has a value between 1 μm and 200 μm, more preferably between 20 μm and 100 μm, and most preferably between 25 μm and 60 μm. In this context, the modulation depth or height is to be understood as a deviation, measured in a direction parallel to the main extension plane, from an intended cylindrical outer course assigned to a narrowest point of the metal-ceramic substrate (measured in planes parallel to the main extension plane). The intended cylindrical outer course extends perpendicular to the main extension plane. It is also conceivable that the modulation depth is caused by the component metallization and/or the ceramic element protruding relative to the backside metallization in a direction parallel to the main extension plane. For example, it is also conceivable that the lateral surface in the area of the ceramic element has a diagonal profile relative to the stacking direction (in other words, the upper surface and the lower surface of the ceramic element have diameters of different sizes).

For example, it is conceivable that the course of the lateral surface or surfaces in the region of the encapsulation, component metallization and/or backside metallization extends parallel to the stacking direction (i.e., the cross-section of the component metallization and/or backside metallization is essentially constant in the region of the component metallization or backside metallization, as viewed in the stacking direction). The modulation depth is then preferably realized by a ledge at the level of the ceramic element. In this case, the modulation depth can be generated by profiling or modulation in the region of the ceramic element, wherein the profiling in stacking direction can be continuous over the thickness of the ceramic element or discrete or abrupt at the height of the ceramic element.

Furthermore, it is conceivable that the insert has one or more ledges which protrude in a direction parallel to the main extension plane relative to the general course of the outer circumference of the insert. This, preferably noselike, ledge can advantageously cause an additional form-fit in the circumferential direction along the outer circumference, which supports a rotationally fixed arrangement in the base body. It has been found in an advantageous manner that such a ledge is formed by cutting out the metal-ceramic substrates from a master card by means of laser light and/or water cutting.

According to a more preferable embodiment, it is intended that the insert has at least one insert-side connection, wherein the at least one insert-side connection is formed on a component side of the insert and is connected to the electrical or electronic component via an through-hole plating, in particular to a component-side connection on the electrical or electronic component, on its side facing away from the metal-ceramic substrate. The connections make it possible in an advantageous manner to control and electrically supply the encapsulated, in particular embedded, electrical or electronic components from the outside of the insert by means of conducting paths and/or insert-side connections. In this case, the through-hole platings reach through the encapsulation and thus form a bond between the outside of the insert and the embedded or encapsulated electrical or electronic component. By means of corresponding electrical or electronic components which have a component side connection on their upper surface, a shortened through-hole plating can thus be provided which realizes an electrical bond with an outer side of the insert. In particular, it is intended that such an insert is advantageous if the insert integrated in the printed circuit board is flush with the component side of the printed circuit board on its upper surface, i.e., on its side facing away from the ceramic substrate. This results in a common plane for the conducting paths on the outside of the printed circuit board and the electrical or electronic component can be recessed into the interior of the printed circuit board, in particular into the interior of the insert, relative to this component side.

Preferably, the metal-ceramic substrate is intended to have a component metallization, a ceramic element and a backside metallization. In particular, a backside metallization proves advantageous to counteract thermomechanical stresses otherwise caused in a metal-ceramic substrate due to the different thermal expansion coefficients of ceramic on one side and metal on the other side. By arranging the component metallization, ceramic element and backside metallization symmetrically, it is possible to counteract a corresponding stress development. This proves to be advantageous for the service life of the insert and thus also on the service life of the printed circuit board.

Preferably, it is intended that the component metallization is structured, wherein preferably a space between two metal sections of the component metallization is filled with material of the encapsulation. In this case, the two metal sections are electrically insulated from each other by the structuring. This allows the respective metal sections to be used individually for different electrical components and their control. In order to bond the respective metal sections electrically to the outside of the insert and/or the printed circuit board, it is intended that further through-hole platings are formed which run from an outer side of the encapsulation, in particular on the component side of the printed circuit board, to the component metallization through the encapsulation.

Preferably, it is intended that the encapsulation surrounds the electrical and/or electronic component and at least part of the metal-ceramic substrate. For example, it is conceivable that, in addition to the electrical or electronic component, the component metallization, the ceramic element and/or the backside metallization are or is surrounded by the encapsulation, in particular on the side of the insert. In this way, it is advantageously possible to provide a sidewall that is formed as far as possible by the material of the encapsulation. This can prove advantageous if it enables a simplified connection of the insert to the base body. For example, it is conceivable that a more effective bond between the encapsulation and the base body can be realized by suitable adhesive means than between the metal-ceramic substrate and the base body. It is also conceivable to incorporate a corresponding profiling in the sidewall to support a form-fitted connection between the base body and insert. Furthermore, it is conceivable that the encapsulation is configured in such a way that it serves as a buffer between the base body and the metal-ceramic substrate, which compensates for corresponding extension of the base body and/or the metal-ceramic substrate. As a result, the service life of the insert and/or the printed circuit board can be improved.

Preferably, a sidewall of the insert is modeled to form a profile, wherein, for example, the ceramic element protrudes with respect to the component metallization and/or the backside metallization in a direction parallel to the main extension plane. In this regard, the ceramic element may, for example, protrude from the encapsulation or protrude with respect to the encapsulation.

Preferably, it is intended that the insert has further through-hole platings which are let into the encapsulation and bond the component metallizations of the metal-ceramic substrate to an insert-side connection of the insert. Preferably, it is intended that a distance dimensioned in stacking direction between the component-side connection and the insert-side connection has a value between 100 μm and 500 μm. This makes it advantageously possible to realize the smallest possible distance between the component-side connection and the insert-side connection, which proves beneficial for communication of the electrical component with the outside of the insert that is as loss-free as possible, in particular without losses due to parasitic inductances.

Furthermore, it is conceivable that the insert has round or rounded corner sections on its periphery in a plane parallel to the main extension plane. This proves advantageous because a core effect can thus be counteracted.

Preferably, the insert comprises a heat sink. This makes it advantageously possible to optimize or adapt the cooling behavior of the insert, especially in the given field of application. For example, it is possible to increase the cooling efficiency in the area of the insert by means of a corresponding individually configured heat sink. In particular, adaptation to the material properties of the insert, i.e., in particular to the metal-ceramic substrate and the encapsulation, is possible. This advantageously allows, for example, sufficient heat dissipation to prevent the insert from tending to separate from the encapsulation and the metal-ceramic substrate due to different thermal expansion coefficients, or to create stresses here.

For example, the heat sink has at least one cooling channel and/or a cooling fin and/or is directly connected to the ceramic element. For example, the cooling channels are loop-like or U-shaped cooling channels integrated into the backside metallization. For this purpose, for example, several metal layers with corresponding recesses are stacked one on top of the other and bonded together by a subsequent bonding process, whereby complex cooling channel structures can be realized which can be used in particular to provide the most homogeneous possible cooling efficiency on the upper surface of the insert. Alternatively, it is conceivable that at least one cooling fin or several cooling fins are connected to the lower surface of the insert in order to be cooled in this way by a common cooling medium, for example a cooling liquid. It is conceivable that the cooling structure is flush with the cooling structure provided by the base body. However, it is also conceivable that the heat sink of the insert projects and/or recedes relative to the back side of the insert or protrudes and/or retracts relative to the cooling structure of the base body.

Preferably, it is intended that at least one wiring level is integrated into the encapsulation. Such a wiring level is particularly suitable for the encapsulation of at least two or more electrical or electronic components, since in this way an electrical contact between the individual components can be realized via the wiring level. For example, it is conceivable that a connection can then be provided via the wiring level with a common through-hole plating on the outside, via which an electrical contact can be made, for example for the purpose of supplying power to the different electrical components.

In particular, it is conceivable that a three-dimensional conductor track structure embedded in the encapsulation is realized by means of preferably several wiring levels and through-hole platings or further through-hole platings. This allows more complex circuits to be integrated into the insert without having to provide complex encapsulations or wiring on the upper surface, which would have to be connected accordingly after insertion of the insert into the printed circuit board.

Preferably, it is intended that the base body have a different material composition than the insert. In other words: While the insert is in particular made of a metal-ceramic substrate encapsulated with a certain material, it is intended that the printed circuit board be preferably free of ceramics or, for example, manufactured from the materials commonly used for printed circuit boards, such as epoxy resin or other fibre-reinforced plastics.

Preferably, it is intended that the encapsulation be made of the base body material and/or plastic, hard paper, and/or epoxy resin. By adapting the encapsulation, in particular to the material of the base body, it is advantageously possible to suppress or even avoid possible stresses between the encapsulation and the base body. However, it can also be advantageous to ensure a specific force-fit between the base body and encapsulation by adapting the materials accordingly, which stabilizes and strengthens the fastening of the insert in the base body.

Furthermore, it is more preferably intended that the insert is configured to be able to be inserted into a formed base body. In other words, the base body is manufactured in one piece and the insert can be inserted into the insert manufactured in one piece. In this more preferably embodiment, the base body is not built around the insert.

Preferably, it is intended that the encapsulation is/is produced by a “compression molding”, “transfer molding” or by a “prepackaging” with preferably plastic, hard paper and/or epoxy resin.

Another object of the present invention is an insert for a printed circuit board according to the invention. All the advantages and properties described for the printed circuit board can also be transferred to the insert analogously, and vice versa.

A further object of the present invention is a method for producing a printed circuit board according to the present invention, wherein an insert and a base body are provided and the insert is inserted into the base body and the insert and the base body are bonded together in an adhesively bonded, force-fitted and/or form-fitted manner. All the advantages and properties described for the printed circuit board can be transferred analogously to the method and vice versa.

Preferably, the insert is profiled in order to achieve a form-fitted connection between the insert and the base body of the printed circuit board in the stacking direction. In particular, it is conceivable that profiling is carried out, for example, by etching, by mechanical machining, for example, by milling, by machining with laser light and/or by a jet of water.

Furthermore, it is intended that holes are let into the encapsulation to realize corresponding through-hole platings that connect the outside of the insert to the electrical or electronic component. Alternatively, it is conceivable that spaces for the subsequent through-hole platings are created during the encapsulation manufacturing process. For example, it is intended for this purpose that a corresponding shape of the mold, in particular of the mold halves, in an injection molding or casting process, for example an injection molding process, ensures that corresponding free spaces are provided for the later through-hole platings. More preferably, it is intended that displaceable mounted stamping elements are let into the mold in order to ensure that these stamping elements are displaced before a cavity is filled and, in particular, are placed on the electrical or electronic components that are embedded on the metal-ceramic substrate. This advantageously prevents the electrical and/or electronic component from being damaged during the encapsulation formation process due to slight displacement changes or changes in position of the component bonded to the metal-ceramic substrate.

Essential components of the metal-ceramic substrates are an insulating layer, which is more preferably manufactured entirely from a ceramic, and at least one metal layer bonded to the insulating layer. Because of their comparatively high insulating strengths, insulating layers manufactured from ceramics have proved particularly advantageous in power electronics. By structuring the metal layer, conducting paths and/or connection areas for the electrical components can then be realized. It is preferably intended that the component metallization of the metal-ceramic substrate intended as insert is not structured but forms a closed surface. A prerequisite for providing such a metal-ceramic substrate is a permanent bond between the metal layer and the ceramic layer. In addition to a so-called direct metal bonding process, i.e., a DCB or DAB process, bonding via an active soldering process, a thick-film coating process, diffusion bonding and/or hot isostatic bonding is also conceivable.

Conceivable materials for the metal layer or metallization are copper, aluminum, molybdenum, tungsten and/or their alloys such as CuZr, AlSi or AlMgSi, as well as laminates such as CuW, CuMo, CuAl and/or AlCu or MMC (metal matrix composite) such as CuW, CuMo or AlSiC. Furthermore, it is more preferably intended that the metal layer or metallization is surface modified on the manufactured metal-ceramic substrate, in particular as component metallization. Conceivable surface modifications include, for example, sealing with a precious metal, in particular silver; and/or gold, or (electroless) nickel or ENIG (“electroless nickel immersion gold”) or edge sealing on the metallization to suppress crack formation or expansion. For example, the metal of the component metallization also differs from the metal of the backside metallization.

Preferably, the ceramic element comprises Al₂O₃, Si₃N₄, AlN, an HPSX ceramic (i.e., a ceramic with an Al₂O₃ matrix comprising an x-percent share of ZrO₂, for example Al₂O₃ with 9% ZrO₂=HPS9 or Al₂O₃ with 25% ZrO₂=HPS25), SiC, BeO, MgO, high-density MgO (>90% of the theoretical density), TSZ (tetragonally stabilized zirconia) as material for the ceramic. It is also conceivable that the ceramic element is configured as a composite or hybrid ceramics, in which several ceramic layers, which each differ in terms of their material composition, are arranged on top of one another and joined together to form a ceramic element in order to combine various desired properties.

Preferably, it is intended that the insert, in particular the metal-ceramic substrate, has a round profile or a rounded corner in the main extension plane. A corresponding shape of the cross-section of the insert in a plane that runs parallel to the main extension plane proves advantageous in particular because a notch effect on the base body of the printed circuit board can be reduced as a result. This in turn can extend the service life of the printed circuit board with insert.

Preferably, it is provided that the metal-ceramic substrate comprises a ceramic element, wherein a component metallization is bonded to the ceramic element, wherein
a backside metallization is provided or formed opposite the component metallizations in a stacking direction running perpendicular to the main extension plane, and/or
a stabilization layer, for example in the form of a further ceramic element, is provided or formed, wherein a metallic intermediate layer is arranged between the ceramic element and the stabilization layer, and/or
the component metallization and/or the backside metallization comprising a first metal layer and/or a second metal layer, wherein the first metal layer and the second metal layer are arranged one above the other.

In particular, it is possible to influence the thermal expansion coefficient of the insert by the corresponding configuration of the metal-ceramic substrate in order to adapt it to the thermal expansion coefficient of the base body. For example, it is conceivable to configure the stabilization layer from a different material or to dimension it accordingly. The thickness of the ceramic element can also be used to optimize the thermomechanical expansion coefficient of the insert in such a way that mechanical stresses between the base body and the insert are reduced. Preferably, the first metal layer differs from a second metal layer with respect to a grain size, wherein more preferably a grain size in the first metal layer is smaller than a grain size in the second metal layer and/or most preferably a thickness of the first metal layer is thinner than a second metal layer. Furthermore, it is conceivable that a thickness of the component metallization is different from a thickness of the backside metallization. In this way, it is advantageously possible to influence a height position of the ceramic element within the base body of the printed circuit board and, in particular, to ensure that the ceramic element having an insulating effect is arranged in the base body offset towards the back side and away from the component side, or vice versa.

In particular, it is intended that the insert re inserted into the base body and that the insert and base body are bonded to each other in an adhesively bonded, force-fitted and/or form-fitted manner.

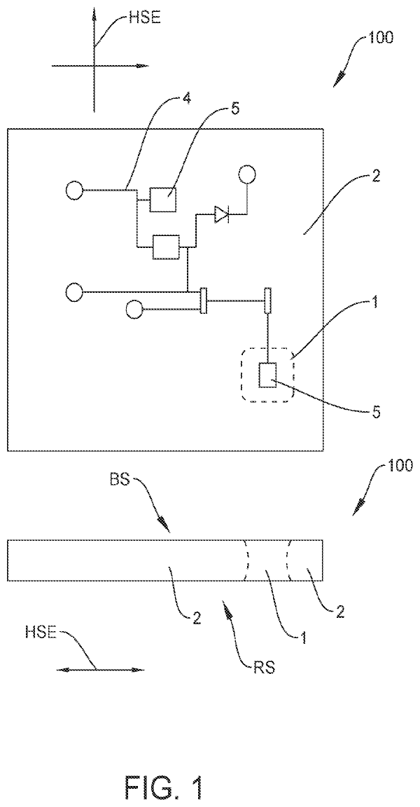

In FIG. 1, a printed circuit board 100 according to a first preferred embodiment of the present invention is shown in a top view (top) and in a sectional view (bottom). Such printed circuit boards 100 serve in particular as carriers for circuits formed by electrical or electronic components 5, connections 7 and/or conducting paths 4. The electrical or electronic components 5, the conducting paths 4 and/or the connections 7, for example in the form of solder pads (pats) or solder lands, are preferably arranged or connected on a component side BS of the printed circuit board 100. For particularly cost-effective production of such printed circuit boards 100, it has become established practice to use plastics, in particular fiber-reinforced plastics, epoxy resin and/or hard paper as materials for a base body 2 which extends essentially along a main extension plane HSE and to whose component side BS electronic components 5 are formed or attached. Preferably, the electrical or electronic components 5 are a power component. Electrical conducting paths 4 can also be understood as an electrical component 5.

Due to the constant further development in the field of electronics, in particular with regard to the performance of the electrical components 5, it has become apparent that the materials used for the base body 2 cannot permanently withstand the new challenges, in particular with regard to the heat generated during operation. This is due in particular to the fact that the materials mentioned for the base body 2 of a printed circuit board 100 have a comparatively low thermal conductivity, which means that the heat generated by the electrical components during operation cannot be dissipated to a sufficient extent.

Printed circuit boards 100 configured as metal-ceramic substrates, on the other hand, can dissipate the heat generated to a sufficient extent due to their increased thermal conductivity, in particular compared with printed circuit boards made from base bodies 2 of the above-mentioned materials, i.e., plastics, in particular fiber-reinforced plastics, epoxy resin and/or hard paper, but are more complex to produce in terms of manufacturing technology and are cost-intensive.

In order to utilize the positive properties of a printed circuit board 100 made of a plastic, an epoxy resin or hard paper and the positive properties of a metal-ceramic substrate, in particular its thermal conductivity, it is preferably intended that the printed circuit board 100 according to the embodiment shown in FIG. 1 has a base body 2 which extends along the main extension plane HSE and into which an insert 1 is integrated, wherein the insert 1 comprises a metal-ceramic substrate 15.

Preferably, it is intended that the insert 1 is arranged in the printed circuit board 100 at such locations where increased heat generation is to be expected.

Preferably, it is intended that at least one insert 1, preferably several inserts 1 are integrated in the base body 2 of the printed circuit board 100. A component side BS of the insert 1 is preferably substantially flush with a component side BS of the base body 2 and/or a back side RS of the insert 1 is flush with the back side RS of the base body 2. Furthermore, it is preferably intended that a proportion of a volume of the insert 1 or the plurality of inserts 1 to the volume of the base body 2 or the entire printed circuit board 100 is less than 30%, more preferably less than 20% and more preferably less than 10%. It has been found that with such low proportions it is already possible to effectively improve the thermal properties of the printed circuit board 100 and at the same time to work predominantly with materials for the base body 2 which are easy to process and less cost-intensive than metal-ceramic substrates 15.

Preferably, it is intended that the insert 1, which in particular is flush on the component side BS and the back side RS with the component side BS and back side RS of the base body 2 in a stacking direction S running perpendicular to the main extending direction HSE, cooperates in a form-fitted, force-fitted and/or adhesively bonded manner with the base body 2 in a direction running perpendicular to the main extending direction HSE. This enables or supports a secure hold of the insert 1 in the printed circuit board 100. In particular, it is intended that a binding is both adhesively bonded and form-fitted. Preferably, it is intended that the selection of the materials, be it a material of the base body 2 on the one hand or one of the materials or several materials of the ceramic element 30, is carried out in such a way that the differences of the thermal expansion coefficients are kept as low as possible in order to prevent thermomechanical stresses from leading to cracks and/or damage to the printed circuit board 100 and/or to the metal-ceramic substrate 15. Preferably, the thermal expansion coefficient of the insert 1 does not deviate from the thermal expansion coefficient of the base body 2 by more than 30%, more preferably by more than 15% and most preferably by more than 10% of the thermal expansion coefficient of the insert 1. To select the inserts in question, the skilled person uses, for example, simulations for the respective compositions of the inserts 1 and compares these with the values for the base body 2.

In particular, it is intended that the insert 1 comprises a metal-ceramic substrate 15 and an electrical and/or electronic component 5. In particular, the electrical and/or electronic component 5 is already bonded, for example soldered, to a component metallization 20 of the metal-ceramic substrate 15 as part of the insert 1. In addition to the metal-ceramic substrate 15 and the electrical and/or electronic component 5, the insert 1 further comprises an encapsulation 10 which encloses the electronic and/or electrical component 5, preferably completely closes it to the component side BS and thus encapsulates it. In this way, an electrical and/or electronic component 5, from which heat is emitted in operation, can already be let into the base body 2 of the printed circuit board 100 together with a metal-ceramic substrate 15 as an insert 1 in an advantageous manner. In this way, such electrical and/or electronic components 5 from which increased heat is emitted during operation can be installed immediately in the corresponding environment so that adequate heat dissipation is ensured.

Preferably, it is intended for this purpose that the insert 1 has a sidewall SW which has a general course which is perpendicular to the main extension plane HSE and connects the component side BS and the back side RS of the insert to one another. Preferably, the sidewall SW is profiled, for example concave and/or convex, to form a form-fitted connection in the assembled state with the base body 2 of the printed circuit board 100.

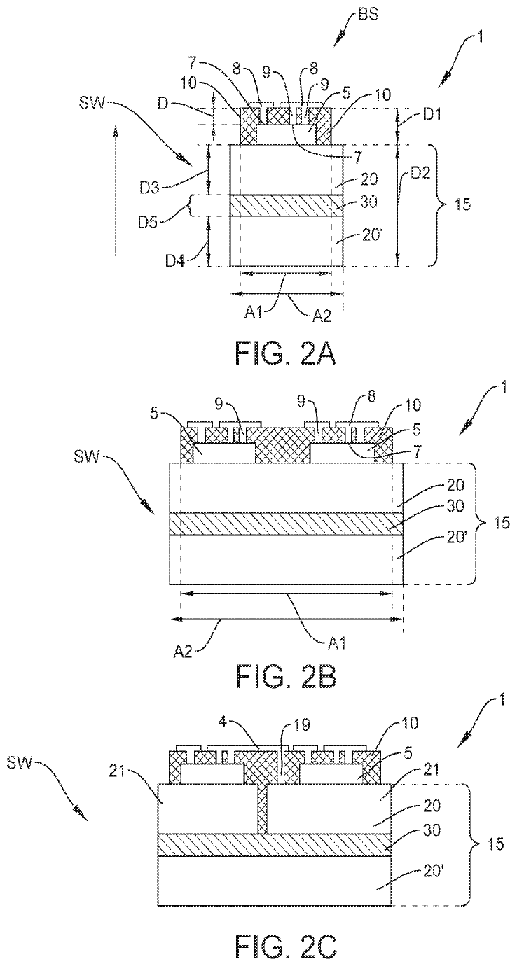

FIGS. 2a-2c show examples of more preferable embodiments of the inserts 1 according to the present invention. In FIG. 2a, an insert 1 is intended in which an encapsulation 10 surrounds the electrical and/or electronic component 5, i.e., surrounds the electrical and/or electronic component 5 on at least three different sides, so that the component 5 is not exposed on any side. In particular, the electrical and/or electronic component 5 is embedded in the encapsulation 10, wherein the encapsulation 10 is solid, i.e., free of cavities. In particular, it is an encapsulation 10 that has been produced within the scope of a pressing, casting or injection molding process. Such encapsulations 10 are solid and can be manufactured comparatively easily. Furthermore, it is preferably intended that insert-side connections 8 are intended on an outer side, in particular on an outer side facing the component side BS in the installed state, of the encapsulation 10. Via these insert-side connections 8, a connection or contacting, for example, to other conducting paths 4 or external lines can be made in the installed state. The insert-side connections 8 are preferably connected to component-side connections 7 via through-hole platings 9 in the encapsulation 10. In particular, these are such component-side connections 7, which are arranged on an upper surface, i.e., on a side of the component 5 facing away from the metal-ceramic substrate 15. Furthermore, it is preferably intended that the encapsulation 10 has a first thickness D1 along a stacking direction S and the metal-ceramic substrate 15 has a second thickness D2. Preferably, the ratio of the first thickness D1 to the second thickness D2 is such that it has a value between 0.1 and 0.7, more preferably between 0.15 and 0.4, and more preferably between 0.18 and 0.23. Furthermore, it is more preferably intended that the encapsulation 10 is dimensioned in such a way that a distance D between the component side connection 7 and the insert-side connection 8, measured in stacking direction S, has a value between 100 μm and 500 μm.

This makes it possible to advantageously realize a connection that is as electrically loss-free as possible between the external insert-side connections 8 and the encapsulated component-side connections 7 on the component 5.

Furthermore, it is most preferably intended that the metal-ceramic substrate 15 has a component metallization 20, a ceramic element 30 and a backside metallization 20′. It is conceivable that a third thickness D3 of the component metallization 20, dimensioned in stacking direction S, is as great as a fourth thickness D4 of the backside metallization 20′, dimensioned in stacking direction S. Thus, a symmetry of front side and back side of the metal-ceramic substrate can be provided, which counteracts bending.

Furthermore, it is intended more preferably that, dimensioned in stacking direction S, the ceramic element 30 has a fifth thickness D5 which has a value between 0.07 mm and 0.4 mm, more preferably between 0.15 and 0.4 mm, and most preferably between 0.22 and 0.28 mm. Due to the insert 1 being insulated in the base body 2, the base body 2 also has a stabilizing effect on the insulating ceramic element 30, so that the mechanical stability for the insert 1 in the installed state is increased. This also allows, for example, a comparatively thin ceramic element 30 to be used. Preferably, the third thickness D3 and/or fourth thickness D4 has a value between 0.1 mm and 0.8 mm, more preferably between 0.15 mm and 0.7 mm, and most preferably between 0.3 and 0.7 mm. It is also conceivable that the third thickness D3 has a value greater than 1.3 mm, more preferably greater than 1.8 mm and most preferably greater than 2 mm.

Furthermore, it is most preferably intended in the embodiment of FIG. 2a that a first extension A1 of the encapsulation 10 measured in a direction extending parallel to the main extension plane HSE is smaller than a second extension A2 of the metal-ceramic substrate 15 measured parallel thereto. As a result, the metal-ceramic substrate 15 protrudes in the direction of the main extension plane HSE with respect to the outermost edge of the encapsulation 10.

In the embodiment example of FIG. 2b, it is intended that the insert 1 comprises, in addition to the electrical and/or electronic component 5, a second electrical and/or electronic component 5 which are connected in combination to the component metallization 20, wherein the electrical and/or electronic components 5 are in electrical contact with each other via the component metallization 20. The protruding of the metal-ceramic substrate 1 with respect to the outermost edge of the encapsulation 10 in a direction parallel to the main extension plane HSE is advantageous in particular because this permits direct contacting of the component metallization 20, in particular coming from the component side BS. In this way, the component metallization 20 can also be used to control the encapsulated or embedded component 5.

In the embodiment shown in FIG. 2c, the component metallization 20 is intended to be structured so that two metal sections 21 insulated from each other are realized in the metal-ceramic substrate 15. In this case, a space between the two metal sections 21 is filled by a material of the encapsulation 10. For example, it is further intended here that conducting paths 4 formed on the outer side of the insert 1, in particular on an outer side of the insert 1 facing the component side BS, are provided to cause an electrical bond between the electrical component 5 of one metal section 21 and the metal section 21 of the further electrical component 5. In particular, it is intended that a further through-hole plating 19 is provided to connect the insert-side connections 8 to the component metallization 20.

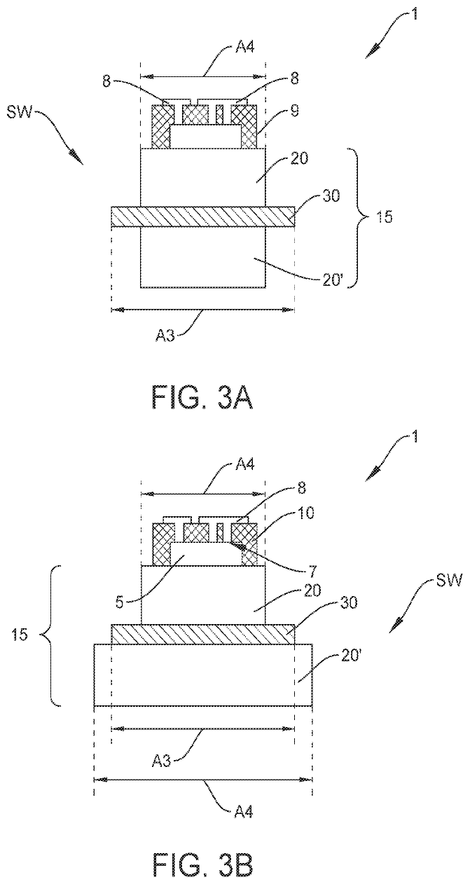

FIGS. 3a and 3b show further embodiments of inserts 1 according to the present invention.

Here, the inserts 1 of FIGS. 3a and 3b differ from that of FIG. 2a essentially only in that the metal-ceramic substrates 15 have a different configuration. In particular, in the embodiment example of FIG. 3a, it is intended that a third extension A3 of the ceramic element along a direction parallel to the main extension plane HSE is greater than a fourth extension A4 of the component metallization 20 and/or the backside metallization 20′. In particular, in the embodiment example of FIG. 3a, it is intended that a fourth extension A4 of the component metallization corresponds to the fourth extension A4 of the backside metallization 20′. The ceramic element 30 protruding at the sidewall SW, in particular the ceramic element 30 protruding with respect to the component metallization 20 and/or the backside metallization 20′, forms a so-called pullback, which contributes to the electrical and/or electronic isolation between the component metallization 20 and the backside metallization 20′. In addition, the protruding portion of the ceramic element 30 can be used to provide a portion suitable for forming a form-fitted connection between the base body 2 of the printed circuit board 100 and the insert 1, thereby further improving the bond between the insert 1 and the printed circuit board 100 in the assembled state. In particular, by protruding with respect to the component metallization 20 and the backside metallization 20′, it is thus possible to realize a form-fit which interacts both in the direction of the component side BS and in the direction of the backside RS, i.e., on both sides, in a direction substantially perpendicular to the main extension plane HSE.

In the embodiment example shown in FIG. 3b, in contrast to the embodiment example of FIG. 3a, it is intended that the fourth extension A4 of the backside metallization 20′ is greater than the fourth extension A4 of the component metallization and greater than the third extension A3 of the ceramic element 30. In this way, an insert 1 is realized which tapers from the back side RS to the component side BS, in particular tapers in a stepped manner. In particular, by appropriately dimensioning the fourth extension A4 of the component metallization 20 and the backside metallization 20′ and the third extension A3 of the ceramic element 30, an outer shape of the metal-ceramic substrate 15 can be realized which can be used in the sense of a key-lock principle to permit, for example, only the insertion of suitable inserts into the corresponding holes in the base body 2 which are predetermined in a corresponding manner by the printed circuit board 100 or the base body. This can prevent, for example, incorrect inserts 1 from being inadvertently inserted into the printed circuit board 100.

Alternatively, it is conceivable that the fourth extension A4 of the backside metallization 20′ is larger than the fourth extension A4 of the component metallization 20 and smaller than the third extension A3 of the ceramic element 30.

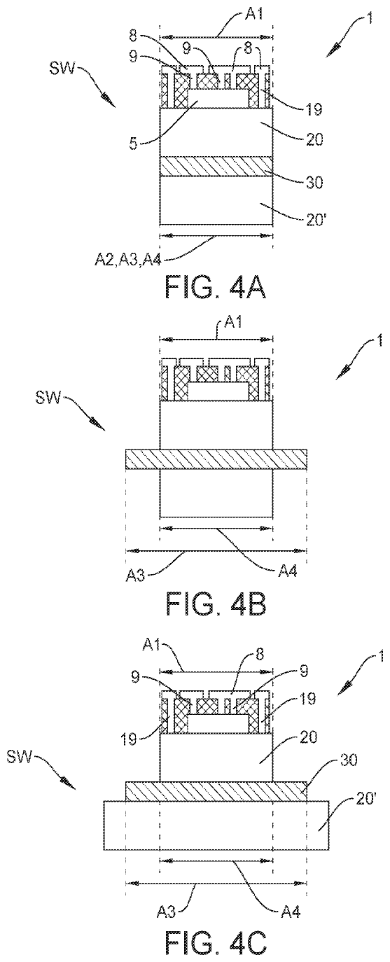

FIGS. 4a-4c show further embodiments of inserts 1 according to the present invention.

In particular, in the embodiments of FIGS. 4a-4c it is intended that the first extension A1 of the encapsulation 10 corresponds to the fourth extension A4 of the component metallization 20. In particular, it is therefore intended that the encapsulation 10 is oriented such that it forms a common plane together with the sidewall SW of the component metallization 10 at the outer periphery or sidewall SW of the insert 1. In order to realize an electrical contact with the component metallization 20, it is most preferably intended that a further through-hole plating 19 is provided which electrically bonds an insert-side connection 8 to the component metallization 20. In a corresponding manner, such a further through-hole plating 19 is also recessed in the encapsulation 10, wherein the further through-hole plating 19 extends from the outside of the encapsulation 10 to the component metallization 20.

The embodiment example of FIG. 4b differs substantially from the embodiment example of FIG. 4a in that the third extension A3 of the ceramic element 30 forming a pullback is greater than a fourth extension A4 of the component metallization 20 and the backside metallization 20′.

In the embodiment example of FIG. 4c, as in the embodiment example of FIG. 3b, the fourth extension A4 of the backside metallization 20′ is larger than the third extension A3 of the ceramic element 30 and the fourth extension A4 of the component metallization 20.

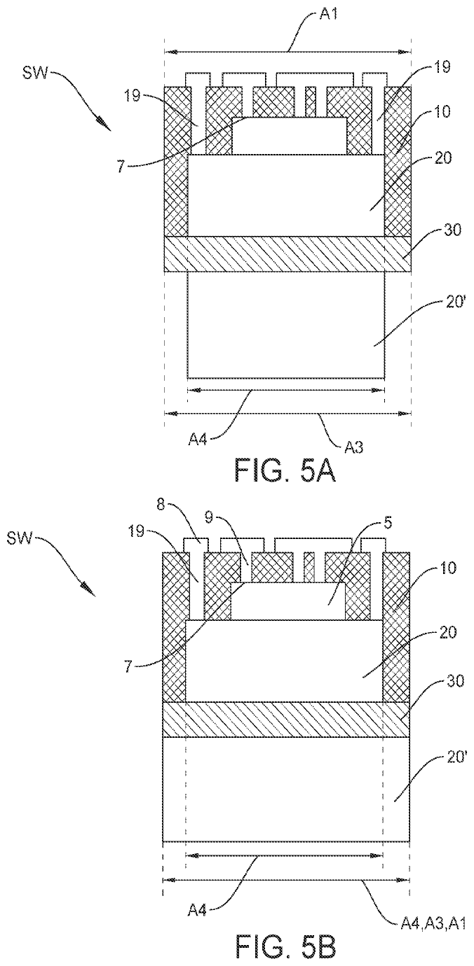

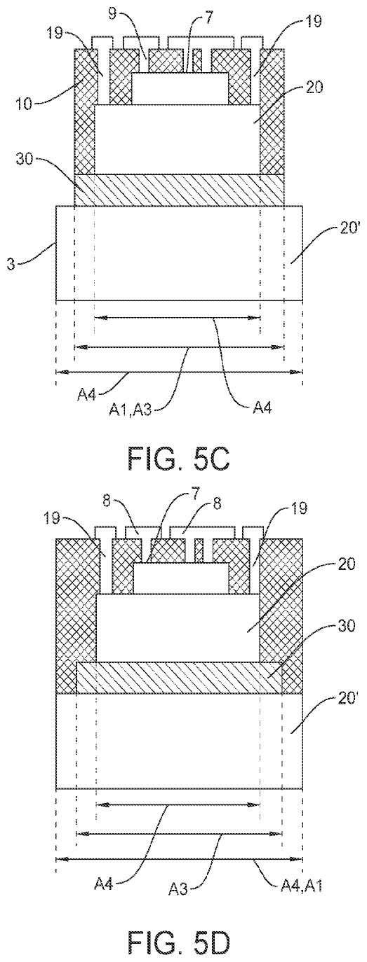

FIGS. 5a-5d show further embodiments for inserts 1 according to the present invention. In each of the FIGS. 5a-5d, it is intended that the encapsulation 10 is configured to also enclose or surround the component metallization 20. In other words, in the embodiments of FIGS. 5a-5d, both the electrical and/or electronic component 5 and the component metallization 20 are embedded in the encapsulation 10, wherein in particular the sidewalls SW of the component metallization 20 are also surrounded or enclosed by the encapsulation 10. This makes it possible to realize additional isolation in the component metallization 20 with respect to the base body 2 of the printed circuit board 100. In the embodiment example shown in FIG. 5a, it is intended that the fourth extension A4 of the backside metallization 20′ substantially corresponds to the fourth extension A4 of the component metallization 20.

In the embodiment example illustrated in FIG. 5b, it is thereby intended that the fourth extension A4 of the backside metallization 20′, on the other hand, substantially corresponds to the first extension A1 of the encapsulation 10 and/or the third extension A3 of the ceramic element 30. This ensures that the encapsulation 10, ceramic element 30 and backside metallization 20 are terminated together towards the side in the insert 1.

In FIG. 5c, it is intended that the fourth extension A4 of the backside metallization 20′ is larger than the first extension A1 of the encapsulation 10 and the third extension A3 of the ceramic element 30, thereby providing a corresponding protruding shape of the backside metallization 20 relative to the outermost circumference of the encapsulation 10 and the ceramic element 30.

In the embodiment example of FIG. 5d, it is further intended that in addition to the electrical component 5 and the component metallization 20, the ceramic element 30 is also enclosed or surrounded by the encapsulation 10. In particular, the sidewalls SW of the ceramic element 30 are surrounded and enclosed by the encapsulation 20. As a result, the ceramic element 30 is spaced from the base body 2 of the printed circuit board 100 in the assembled state.

Furthermore, it is preferably provided that in the embodiment example of FIG. 5d the fourth extension A4 of the backside metallization 20′ substantially corresponds to the first extension A1 of the encapsulation 10, while the fourth extension A4 of the component metallization 20 is smaller than the fourth extension A4 of the backside metallization 20′.

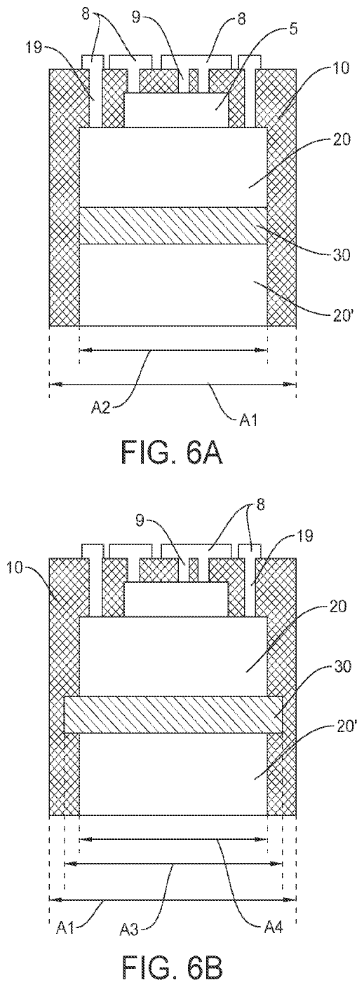

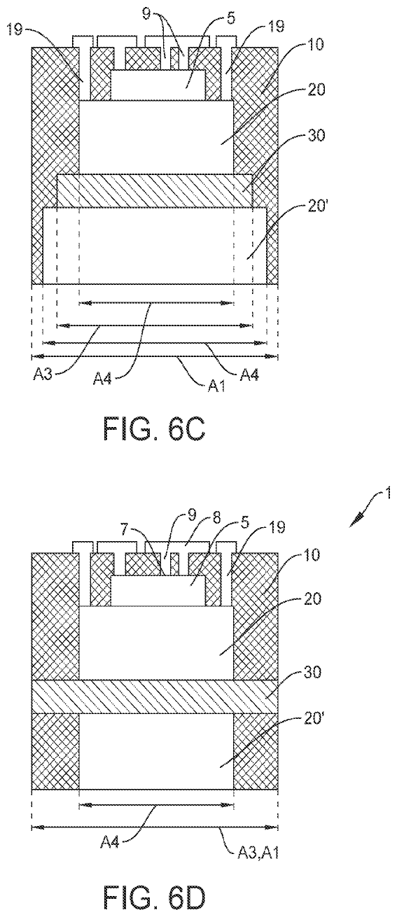

FIGS. 6a-6d show further embodiments of inserts 1 according to the present invention. Thereby, in the embodiments of FIGS. 6a-6d, it is intended that the encapsulation 10 surrounds the electrical and/or electronic component 5, the component metallization 20 and the backside metallization 20′. In the embodiment example shown in FIG. 6a, the encapsulation 10 completely covers the sidewalls SW of the insert 1. This proves to be advantageous in particular if the appropriate formation of the encapsulation 10 facilitates the bond to the base body 2, for example by means of a suitable adhesive to the base body 2. Furthermore, in the embodiment example of FIG. 6a, it is intended that the third extension A3 of the ceramic element 30 corresponds to the fourth extension A4 of the component metallization and the backside metallization 20′. In particular, it is intended that the encapsulation 10 is configured such that the sidewalls SW of the electrical and/or electronic component 5, the component metallization 20, the ceramic element 30 and the backside metallization 20′ are sealed by the encapsulation 10.

The embodiment example of FIG. 6b differs from the embodiment example of FIG. 6a only in that the ceramic element 30 for forming a pullback has a third extension A3 which is larger than the fourth extension A4 of the component metallization 20 and/or the backside metallization 20′, but is smaller than the first extension A1 of the encapsulation.

In the embodiment example of FIG. 6c, it is intended that the fourth extension A4 of the backside metallization 20′ is larger than the third extension A3 of the ceramic element 30 and the fourth extension A4 of the component metallization 20. In the embodiments of FIGS. 6b and 6c, likewise the electrical component 5, the component metallization 20, the ceramic element 30 and the backside metallization 20′ are each enclosed at their sidewalls SW by the encapsulation 10, so that the sidewalls SW of the insert 1 are formed exclusively from material of the encapsulation 10. In the FIG. 6d, it is intended that the third extension A3 substantially corresponds to the first extension A1 of the encapsulation 10. In other words, the ceramic element 30 in the insert 1 extends to the sidewall of the insert 1 and here is flush with the encapsulation 10, preferably forming a portion of the sidewall SW.

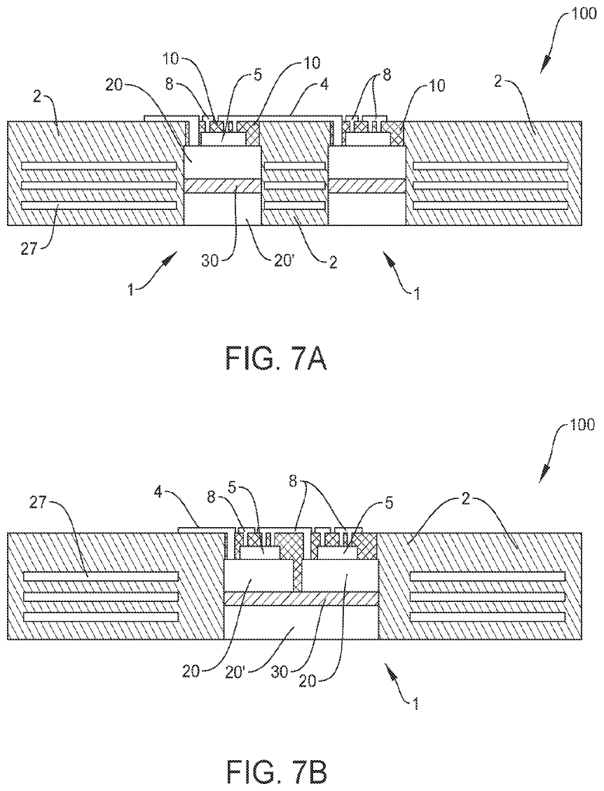

FIGS. 7a and 7b show printed circuit boards 100 according to more preferable embodiments of the present invention. In particular, it is intended that in FIG. 7a two inserts 1 are let into a base body 2 to form a printed circuit board 100. It is conceivable that the printed circuit board 100, in particular the base body 2, comprises further conductor elements 27 which are integrated in the base body 2, for example in order to make lateral contact with the component metallization 20 and/or backside metallization 20′ of the insert 1.

Furthermore, it is conceivable that, in the installed state, conducting paths 5 on the base body 2 of the printed circuit board 100 are connected to the insert-side connections 8, for example via corresponding conducting paths 4. Furthermore, it is most preferably intended that, on the component side BS and/or back side RS of the printed circuit board 100, the outside of the base body 2 is largely flush with the outside of the encapsulation 10 and/or the backside metallization 20′. This allows the connections and/or conducting paths 4 on the outside of the insert 1 and on the base body 2 to be arranged on one plane. In other words, it is more preferably intended that in the printed circuit boards 100 the electrical or electronic components 5 of the inserts 1 are recessed with respect to an outer side of the base body 2 into the interior of the printed circuit board 100, namely within the insert 1. In other words, the electrical or electronic components 5 are offset inwardly with respect to the outside, in particular the component side BS of the printed circuit board 100 and are integrated into the printed circuit board 100.

In the embodiment example of FIG. 7b, it is intended that an insert 1 is provided which has a structured component metallization 20. The metal sections 21 of the component metallization 20 of this insert 1 can, for example, be electronically bonded to one another via conducting paths 4 on the base body 2 and/or on the insert 1.

Furthermore, it is conceivable that the backside metallization 20 protrudes from the base body 2 in order to ensure a good thermal connection to a cooling element.

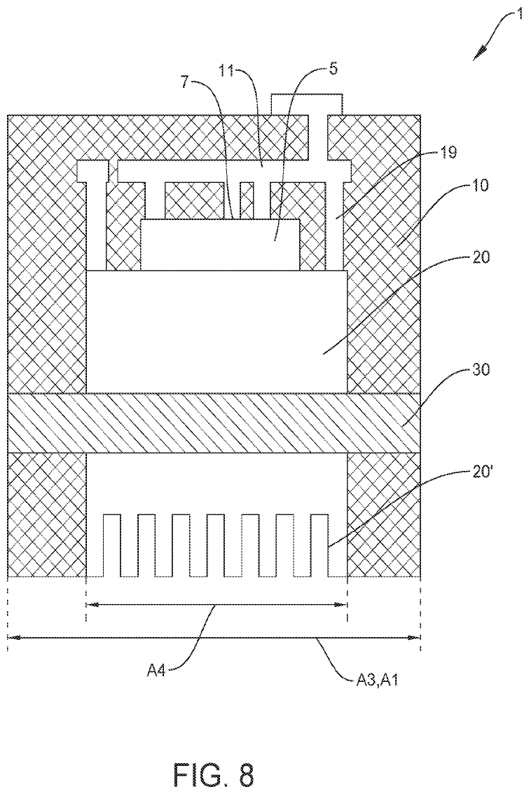

FIG. 8 shows another example of an embodiment of an insert 1 according to the present invention. In particular, the embodiment example shown in FIG. 8 comprises two further features, which individually or collectively can also be integrated in any other embodiment protruded or listed above. This applies in particular to the different dimensions of component metallizations 20 and backside metallizations 20′ or the different shapes of encapsulations 10, which are exemplified in the preceding figures. In particular, the embodiment example is characterized by the fact that a wiring plane 11 is integrated into the encapsulation 10. By means of such a wiring level 11, which is arranged in particular within the encapsulation 10, it is advantageously possible to combine contacts to different components 5 and to make them available to a common connection on the outside of the encapsulation 10. For this purpose, the wiring level 11 extends, for example, in the form of a metal layer, essentially parallel to the main extension plane HSE and, in particular, perpendicular and/or diagonal to the direction of extension of the through-hole platings 9, which are in contact with the component metallization 20 and/or an upper surface of the electrical or electronic component 5. It is also conceivable that several wiring levels 11 are integrated within the encapsulation 10, which, in particular, are at different distances from the upper surface of the component metallization 20.

In particular, it is advantageous to integrate a corresponding wiring level 11 in such encapsulations 10 that enclose or cover at least two electrical components 5 with each other. In particular, the electrical components 5 are in electrical contact with each other via the wiring level 11. In particular, it is intended that the wiring level 11 is arranged between the upper surface of the encapsulation 10 and the electronic component 5 and, in particular, a direct, electrical contact to a component side connection 7, in particular on its upper surface, is realized via the wiring level 11. This also makes it advantageously possible, for example, to provide a supply voltage to the various electrical components 5 via a common connection on the outside of the encapsulation 10. In particular, it is conceivable that a three-dimensional conductor track structure is integrated into the encapsulation 10 by means of various wiring levels 11 and through-hole platings 9 or further through-hole platings 19.

A further feature of the embodiment example of FIG. 8, which can also be integrated in all other embodiments of the present invention, is the design of the backside metallization 20′ as a heat sink 40 or the formation of a heat sink 40 on a cooling side or back side RS of the insert 1. In this context, it is conceivable that the heat sink 40 is structureless and/or has at least one fin and/or comprises a cooling channel, in particular a U-shaped cooling channel, in order to allow a cooling liquid to penetrate the heat sink 40 and thereby dissipate heat from the component side BS. In particular, it is conceivable that a plurality of loop-like or U-shaped cooling channels are integrated into the heat sink 40 in order to provide cooling as homogeneously as possible in the region of the insert 1. Preferably, the heat sink of the insert 1 is configured separately from the heat sink 40 of the base body 2 of the printed circuit board 100. This makes it advantageously possible to intend individual cooling for the insert 1, for example, in order to cope with correspondingly increased heat loads. Alternatively, it is also conceivable that the heat sink 40 of insert 1 is part of the heat sink of the entire printed circuit board 100, i.e., in particular of base body 2. In this case, the heat sinks 40 of the insert 1 and of the base body 2 lie in one plane and/or merge into one another essentially seamlessly in the assembled state, at least on the cooling side or back side RS. Furthermore, it is conceivable that the heat sink structure or the heat sink 40 in the region of the insert 1 and the heat sink structure or the heat sink 40 in the region of the base body 2 differ from one another or are substantially similar, at least of the same type. It is also conceivable that the heat sink 40 is directly bonded to the ceramic element 30, i.e., in particular directly bonded to the ceramic element 30 by an active soldering process by hot isostatic pressing or by a direct metal bonding process.

### REFERENCE NUMERALS

1 Insert
2 Base body
4 Conducting paths
5 Component
7 Component side connection
8 Insert-side connection
9 through-hole plating
10 Encapsulation
11 Wiring level
15 Metal-ceramic substrate
19 through-hole platings
20 Component metallization
20′ Backside metallization
21 Metal section
27 Conductor element
30 Ceramic element
40 Heat sink
100 Printed circuit board
HSE Main extension plane
A1 First extension
A2 Second extension
A3 Third extension
A4 Fourth extension
D1 First thickness
D2 Second thickness
D3 Third thickness
D4 Fourth thickness
D5 Fifth thickness
D Distance
S Stacking direction
RS Back side
BS Component side

1-15. (canceled)

16. A printed circuit board (100) for electrical components (5) and/or conducting paths (4), comprising
a base body (2) extending along a main extension plane (HSE), and
an insert (1) integrated in the base body (2),
wherein the insert (1) comprises a metal-ceramic substrate (15), an electrical and/or electronic component (5) and an encapsulation (10) enclosing at least the electrical and/or electronic component (5), wherein, in addition to the electrical and/or electronic component, a component metallization, a ceramic element and/or a backside metallization of the metal-ceramic substrate (15) is surrounded by the encapsulation at the side of the insert, wherein the ceramic element protrudes with respect to the component metallization and/or backside metallization.

17. The printed circuit board (100) according to claim 16, wherein the insert (1) has at least one insert-side connection (8), wherein the at least one insert-side connection (8) is formed on a component side (B S) of the insert (1) and is connected to the electrical and/or electronic component (5) via a through-hole plating (9) in the encapsulation (10).

18. The printed circuit board (100) according to claim 16, wherein the metal-ceramic substrate (15) comprises a component side metallization (20) and a ceramic element (30).

19. The printed circuit board (100) according to claim 16, wherein the component metallization (20) is structured.

20. The printed circuit board (100) according to claim 16, wherein the encapsulation (10) surrounds the electrical and/or electronic component (5) and at least a portion of the metal-ceramic substrate (15).

21. The printed circuit board (100) according to claim 16, wherein a sidewall (SW) of the insert (1) is modulated to form a profile, for example wherein the ceramic element (30) protrudes with respect to the component metallization (20) and/or the backside metallization (20′) in a direction parallel to the main extension plane (HSE).

22. The printed circuit board (100) according to claim 16, wherein the insert (1) comprises a further through-hole plating (19) which is recessed into the encapsulation (10) and which bonds the component metallization (20) of the metal-ceramic substrate (15) to an insert-side connection (8) of the insert (1).

23. The printed circuit board (100) according to claim 17, wherein a distance (D) dimensioned in the stacking direction (S) between the component-side connection (7) and the insert-side connection (8) has a value between 100 μm and 500 μm.

24. The printed circuit board (100) according to claim 16, wherein the insert (1) comprises a heat sink (40).

25. The printed circuit board according to claim 24, wherein the heat sink (40) comprises at least one cooling channel and/or comprises at least one cooling fin and/or is directly connected to the ceramic element (30).

26. The printed circuit board (100) according to claim 16, wherein at least one wiring level (11) is integrated into the encapsulation (10).

27. The printed circuit board (100) according to claim 16, wherein the base body (2) has a different material composition than the insert (1).

28. The printed circuit board (100) according to claim 16, wherein the encapsulation (10) is manufactured
from the material of the base body (2) and/or
from plastic, hard paper and/or epoxy resin.

29. The insert (1) for a printed circuit board (100) according to claim 16, wherein the insert (1) comprises a metal-ceramic substrate (15) as well as an electrical and/or electronic component (5) and an encapsulation (10) surrounding at least the electrical and/or electronic component (5), wherein, in addition to the electrical and/or electronic component, a component metallization, a ceramic element and/or a backside metallization of the metal-ceramic substrate (15) is also surrounded by the encapsulation at the side of the insert, wherein the ceramic element protrudes with respect to the component metallization and/or backside metallization.

30. The method of manufacturing a printed circuit board (100) according to claim 16, wherein
an insert (1) according to claim 14 and a base body (2) are provided,
the insert (1) is inserted into the base body (2), and
the insert (1) and base body (2) are adhesively bonded, force-fitted and/or form-fitted to one another.

31. The printed circuit board (100) according to claim 17, wherein the at least one insert-side connection (8) is connected to a component-side connection (7) on the electrical and/or electronic component (5) on its side facing away from the metal-ceramic substrate (15).

32. The printed circuit board (100) according to claim 18, wherein the metal-ceramic substrate (15) further comprises a backside metallization (20′).

33. The printed circuit board (100) according to claim 19, wherein a space between two metal sections (21) of the structured component metallization (20) is filled with material from the encapsulation (10).
